(19) United States
(12) Patent Application Publication
(10) Pub. No.: US 2006/0131699 A1
(43) Pub. Date: Jun. 22, 2006

(54) Technique for forming a substrate having crystalline semiconductor regions of different characteristics located above a buried insulating layer

(76) Inventors: Michael Raab, Radebeul (DE); Andy Wei, Dresden (DE); Manfred Horstmann, Duerrhoehrsdorf-Dittersbach (DE)

Correspondence Address: WILLIAMS, MORGAN & AMERSON, 10333 RICHMOND, SUITE 1100, HOUSTON, TX, 77042, US

(21) Appl. No.: 11/185,391

(22) Filed: Jul. 20, 2005

(30) Foreign Application Priority Data
Dec. 17, 2004 (DE) 10 2004 060 961.6

(51) Int. Cl. H01L 29/04

(52) U.S. Cl. 257/627

(57) ABSTRACT

By using an implantation technique for forming a buried insulation layer, an SOI-type configuration may be achieved for hybrid orientation substrates, thereby significantly enhancing the further fabrication processes in forming circuit elements on differently oriented semiconductor regions. Consequently, process complexity for methodology and production steps is significantly reduced compared to fabrication processes based on conventional hybrid orientation substrates.

### BACKGROUND OF THE INVENTION

1. Field of the Invention

Generally, the present invention relates to the formation of integrated circuits, and, more particularly, to the formation of crystalline semiconductor regions of different characteristics, such as different charge carrier mobilities in channel regions of a field effect transistor, on a single substrate.

2. Description of the Related Art

The fabrication of integrated circuits requires the formation of a large number of circuit elements on a given chip area according to a specified circuit layout. Generally, a plurality of process technologies are currently practiced, wherein, for complex circuitry, such as microprocessors, storage chips and the like, MOS technology is currently the most promising approach due to the superior characteristics in view of operating speed and/or power consumption and/or cost efficiency. During the fabrication of complex integrated circuits using MOS technology, millions of transistors, i.e., N-channel transistors and/or P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely doped channel region disposed between the drain region and the source regions.

The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on the dopant concentration, the mobility of the charge carriers, and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially determines the performance of MOS transistors. Thus, the reduction of the channel length, and associated therewith the reduction of the channel resistivity, renders the channel length a dominant design criterion for accomplishing an increase in the operating speed of the integrated circuits.

The continuing shrinkage of the transistor dimensions, however, entails a plurality of issues associated therewith that have to be addressed so as to not unduly offset the advantages obtained by steadily decreasing the channel length of MOS transistors. One major problem in this respect is the development of enhanced photolithography and etch strategies to reliably and reproducibly create circuit elements of critical dimensions, such as the gate electrode of the transistors, for a new device generation. Moreover, highly sophisticated dopant profiles, in the vertical direction as well as in the lateral direction, are required in the drain and source regions to provide low sheet and contact resistivity in combination with a desired channel controllability. In addition, the vertical location of the PN junctions with respect to the gate insulation layer also represents a critical design criterion in view of leakage current control. Hence, reducing the channel length also requires reducing the depth of the drain and source regions with respect to the interface formed by the gate insulation layer and the channel region, thereby requiring sophisticated implantation techniques. According to other approaches, epitaxially grown regions are formed with a specified offset to the gate electrode, which are referred to as raised drain and source regions, to provide increased conductivity of the raised drain and source regions, while at the same time maintaining a shallow PN junction with respect to the gate insulation layer.

Since the continuous size reduction of the critical dimensions, i.e., the gate length of the transistors, necessitates the adaptation and possibly the new development of highly complex process techniques concerning the above-identified process steps, it has been proposed to also enhance device performance of the transistor elements by increasing the charge carrier mobility in the channel region for a given channel length, thereby offering the potential for achieving a performance improvement that is comparable with the advance to a future technology node while avoiding many of the above process adaptations associated with device scaling. In principle, at least two mechanisms may be used, in combination or separately, to increase the mobility of the charge carriers in the channel region. First, the dopant concentration within the channel region may be reduced, thereby reducing scattering events for the charge carriers and thus increasing the conductivity. However, reducing the dopant concentration in the channel region significantly affects the threshold voltage of the transistor device, thereby presently making a reduction of the dopant concentration a less attractive approach unless other mechanisms are developed to adjust a desired threshold voltage.

Second, the lattice structure, typically a (100) surface orientation, in the channel region may be modified, for instance by creating tensile or compressive stress to produce a corresponding strain in the channel region, which results in a modified mobility for electrons and holes, respectively. For example, creating tensile strain in the channel region increases the mobility of electrons, wherein, depending on the magnitude and direction of the tensile strain, an increase in mobility of 120% or more may be obtained, which, in turn, may directly translate into a corresponding increase in the conductivity. On the other hand, compressive strain in the channel region may increase the mobility of holes, thereby providing the potential for enhancing the performance of P-type transistors. The introduction of stress or strain engineering into integrated circuit fabrication is an extremely promising approach for further device generations, since, for example, strained silicon may be considered as a “new” type of semiconductor material, which may enable the fabrication of fast powerful semiconductor devices without requiring expensive semiconductor materials and manufacturing techniques.

Consequently, it has been proposed to introduce, for instance, a silicon/germanium layer or a silicon/carbon layer in or below the channel region to create tensile or compressive stress that may result in a corresponding strain. Although the transistor performance may be considerably enhanced by the introduction of stress-creating layers in or below the channel region, significant efforts have to be made to implement the formation of corresponding stress layers into the conventional and well-approved MOS technique. For instance, additional epitaxial growth techniques have to be developed and implemented into the process flow to form the germanium- or carbon-containing stress layers at appropriate locations in or below the channel region. Hence, process complexity is significantly increased, thereby also increasing production costs and the potential for a reduction in production yield.

Thus, in other approaches, external stress created by, for instance, overlaying layers, spacer elements and the like is used in an attempt to create a desired strain within the channel region. However, the process of creating the strain in the channel region by applying a specified external stress suffers from a highly inefficient translation of the external stress into strain in the channel region, since the channel region is strongly bonded to the buried insulating layer in silicon-on-insulator (SOI) devices or the remaining bulk silicon in bulk devices. Hence, although providing significant advantages over the above-discussed approach requiring additional stress layers within the channel region, the moderately low strain obtained renders the latter approach less attractive.

Recently, it has been proposed to provide so-called hybrid orientation substrates that include silicon regions of two different orientations, that is, a (100) surface orientation and a (110) surface orientation, due to the well-known fact that the hole mobility in (110) silicon is approximately 2.5 times the mobility in (100) silicon. Thus, by providing a (110) channel region for P-channel transistors in CMOS circuits while maintaining the (100) orientation providing a superior electron mobility in the channel regions of the N-channel transistors, the performance of circuits containing both types of transistors may significantly be enhanced for any given transistor architecture.

FIG. 1 schematically shows a cross-sectional view of a typical conventional hybrid orientation substrate that may be used for the formation of transistor elements in and on silicon regions having different orientations. In FIG. 1, a substrate 100 comprises a base substrate 101, which is comprised of crystalline silicon having a specified crystallographic orientation such as a (110) orientation. Formed in the base substrate 101 is a shallow trench isolation structure 102 comprised of insulating materials, such as silicon dioxide, silicon nitride and the like. Thus, the trench isolation structure 102 defines a crystalline region 106 having the (110) orientation and having a configuration as is typical for a silicon bulk substrate. Separated by the trench isolation structure 102 from the region 106 is a region 105 including a crystalline silicon region 103 having a different orientation, such as a (100) orientation, wherein the region 103 is bounded in the depth direction by a buried oxide layer 104. Consequently, the region 105 represents a typical SOI configuration.

The substrate 100 may be formed by well-established wafer bond techniques to form a substrate having the buried oxide layer 104 and the silicon layer 103 formed above the (110) substrate 101. Thereafter, advanced etch techniques are used to form an opening through the silicon layer 103 and the buried oxide layer 104 to expose a portion of the base substrate 101. Next, well-established selective epitaxial growth methods are employed to form a (110) silicon in the opening. After planarizing the resulting structure and forming the shallow trench isolations 102 by well-established techniques to obtain the substrate 100, transistor elements may be formed in and on the regions 106, 105 in conformity with device requirements.

Although the conventional substrate 100 provides significant advantages with respect to device performance, as for example P-channel transistors may be formed preferably in and on the region 106, while N-channel transistors may preferably be formed in and on the region 105, significant efforts are required to adapt and/or develop process and metrology techniques that simultaneously meet the requirements for SOI devices and bulk devices. For instance, many measurement procedures during the manufacturing process require different strategies for SOI devices, formed on the region 105, compared to bulk devices, formed on the region 106, thereby requiring a great deal of effort and production time to produce the required measurement results. In addition, process steps, such as etching and rapid thermal annealing, which are used during the fabrication of transistor elements are quite sensitive to substrate properties, thereby also requiring significant efforts in adapting existing techniques and developing new process recipes when processing the hybrid substrate, thereby contributing to the overall process complexity.

In view of the above-described situation, there exists a need for an improved technique that enables providing semiconductor regions of different characteristics, such as different orientations, while eliminating or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention relates to a technique that enables the formation of crystalline semiconductor regions of different characteristics, such as different crystallographic orientations, wherein the semiconductor regions are formed above an insulating layer, thereby providing the potential for using well-established process techniques, such as SOI techniques, for each of the different crystalline semiconductor regions. Consequently, a significant performance enhancement for the transistors may be obtained similarly as in conventional hybrid orientation substrates, while the constraints regarding the manufacturing processes for circuit elements are significantly relaxed, since a single substrate architecture with a buried insulating layer, such as an SOI configuration, is provided, thereby reducing production cost and increasing production yield.

In accordance with one illustrative embodiment of the present invention, a method comprises forming a hybrid semiconductor substrate by forming a first crystalline semiconductor layer having a first characteristic above a second crystalline semiconductor layer having a second characteristic that differs from the first characteristic. Furthermore, an opening is formed in the first crystalline semiconductor layer to expose a portion of the second crystalline semiconductor layer. Moreover, a crystalline semiconductor material is formed in the opening by epitaxial growth to form a crystalline semiconductor material in the opening having the second characteristic. Finally, a buried insulation layer is formed under the formed crystalline semiconductor material in the opening in the hybrid substrate by ion implantation and annealing.

According to another illustrative embodiment of the present invention, a substrate for forming transistor elements comprises a base substrate having formed thereon a buried insulation layer. The substrate further comprises a first crystalline semiconductor region formed on the buried insulation layer, wherein the first crystalline semiconductor region has a first characteristic that represents at least one of a crystallographic orientation, a type of semiconductor material and an intrinsic strain thereof. The substrate further comprises a second crystalline semiconductor region formed on the buried insulation layer and having a second characteristic that differs from the first characteristic, wherein the second characteristic represents at least one of a crystallographic orientation, a type of semiconductor material and an intrinsic strain thereof. Moreover, the substrate comprises an isolation structure laterally isolating the first and second semiconductor regions.

According to yet another illustrative embodiment of the present invention, a semiconductor device comprises a base substrate having formed thereon a buried insulation layer. The semiconductor device further comprises a first crystalline semiconductor region formed on the buried insulation layer and having a first characteristic that represents at least one of a crystallographic orientation, a type of semiconductor material and an intrinsic strain thereof. The semiconductor device further comprises a second crystalline semiconductor region formed on the buried insulation layer and having a second characteristic that differs from the first characteristic and that represents at least one of a crystallographic orientation, a type of semiconductor material and an intrinsic strain thereof. The device further comprises an isolation structure laterally isolating the first and second semiconductor regions. Moreover, the device comprises a first transistor element formed in and on the first crystalline semiconductor region and a second transistor element formed in and on the second crystalline semiconductor region.

### BRIEF DESCRIPTION OF THE DRAWINGS

The invention may be understood by reference to the following description taken in conjunction with the accompanying drawings, in which like reference numerals identify like elements, and in which:

FIG. 1 schematically shows a cross-sectional view of a conventional hybrid orientation substrate with an SOI region and a bulk silicon region;

FIGS. 2a-2g schematically show cross-sectional views of a hybrid substrate during various manufacturing stages in accordance with illustrative embodiments of the present invention; and

FIGS. 3a-3c schematically show cross-sectional views of a hybrid substrate during various manufacturing stages, in which a buried insulation layer is entirely formed by a SIMOX implantation sequence in accordance with further illustrative embodiments of the present invention.

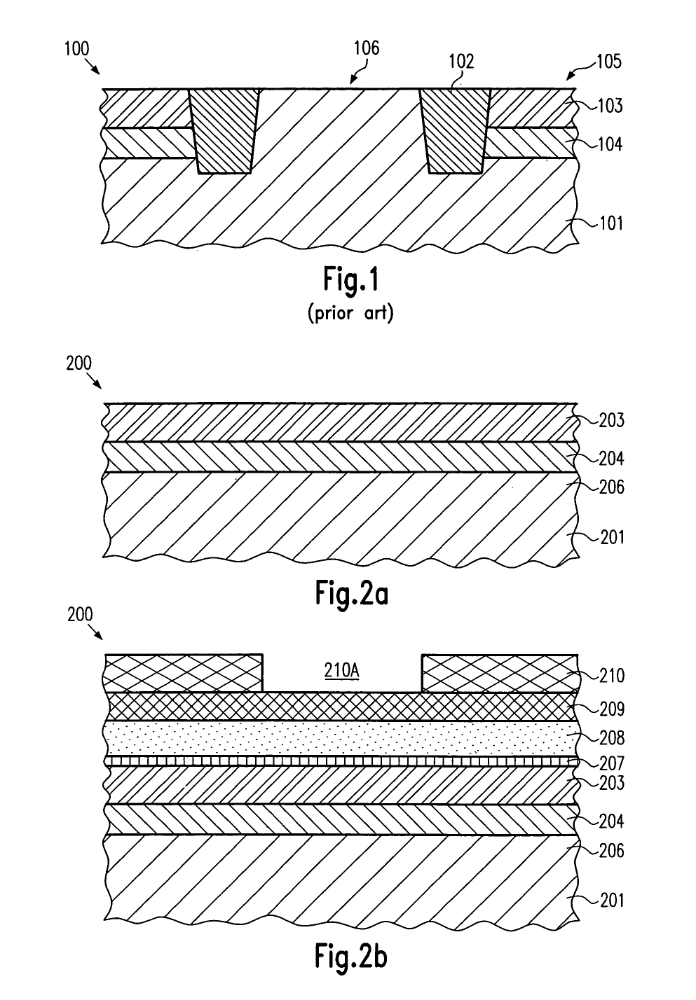

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is based on the concept that the manufacturing process for circuit elements formed on hybrid substrates, such as substrates including semiconductor regions of different crystallographic orientations, may significantly be enhanced by providing a buried insulation layer, such as a buried oxide layer, for each of the different crystalline semiconductor regions to enable the use of a common transistor architecture in the different crystalline regions. Hereby, the SIMOX (Separation by IMplantation of OXygen) technique may advantageously be used to form locally or globally a buried insulation layer at a specified depth. The SIMOX technique, which is conventionally employed for forming SOI substrates, is based on a specific implantation technique for introducing oxygen to a specified depth, without substantially amorphizing the overlying crystalline region. This may be accomplished by performing the oxygen implantation at elevated temperatures, such as approximately 400-600° C., so that implantation-induced damage is immediately repaired, at least to a certain degree, so that, even after the required high dose implantation, the damaged silicon region above the implanted oxygen may substantially be re-crystallized during an anneal cycle, while a buried oxide layer is formed. The introduction of the high oxygen concentration, for instance requiring a dose of approximately 10¹⁸ ions/cm², may be accomplished by modern SIMOX implanters providing a high beam current at a moderately high uniformity across the substrate. Appropriate implantation tools, available for instance from IBIS Technology Corporation, and corresponding well-established SIMOX techniques may advantageously be used in forming buried insulation layers in accordance with the present invention, as will be described in more detail with reference to the accompanying drawings.

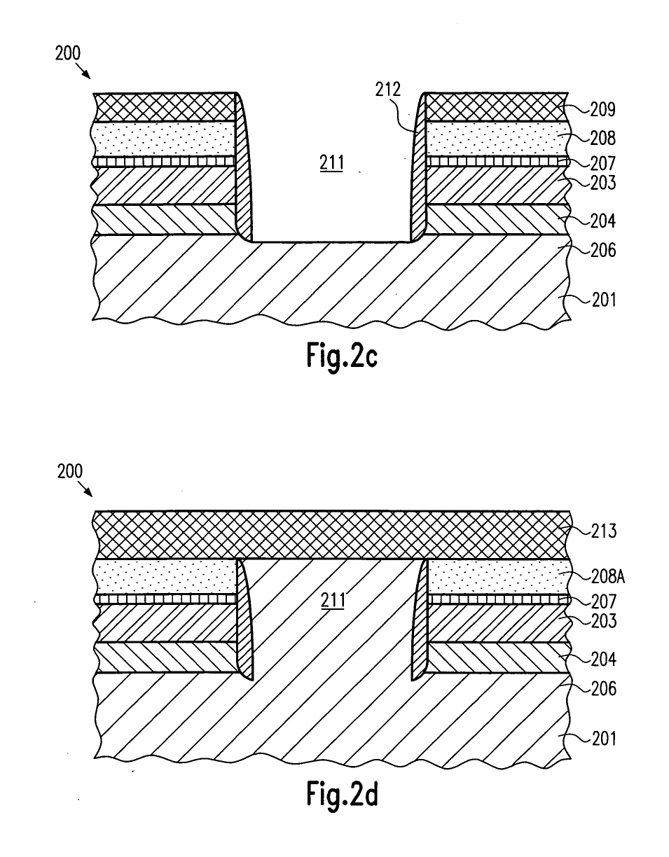

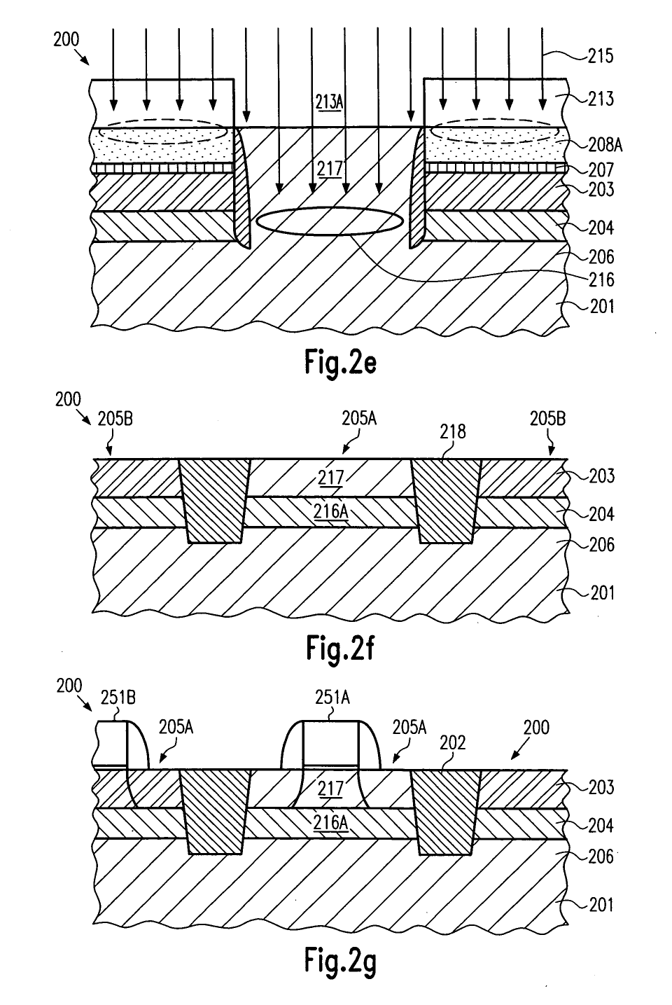

FIG. 2a schematically shows a cross-sectional view of a substrate 200 during an initial manufacturing stage. The substrate 200 comprises a base substrate 201 having formed thereon a crystalline semiconductor layer 206, which has a specified characteristic. For instance, the specific characteristic may represent the crystallographic orientation and/or the type of semiconductor material forming the layer 206 and/or an intrinsic strain of the layer 206. In one particular embodiment, the crystalline semiconductor layer 206 represents a silicon layer having a specific crystallographic orientation, such as a (110) orientation or a (100) orientation, as these two orientations provide an enhanced hole mobility and electron mobility, respectively. In particular embodiments, the crystalline semiconductor layer 206 is an upper portion of the base substrate 201 that is provided as a crystalline substrate. A further crystalline semiconductor layer 203 having a specific characteristic that differs from the characteristic of the semiconductor layer 206 is formed above the semiconductor layer 206, wherein the layers 203, 206 are separated by an insulation layer 204. The insulation layer 204 may represent any appropriate insulating layer, such as an oxide layer, for instance a silicon dioxide layer, a silicon nitride layer and the like. Moreover, the layer 204 may be comprised of two or more sub-layers, each formed from an insulating material.

The crystalline semiconductor layer 203 may be characterized by its crystallographic orientation and/or the type of semiconductor material and/or the intrinsic strain thereof, similarly as is described with reference to the layer 206, wherein the layers 203, 206 differ at least in one of these properties. In one particular embodiment, the semiconductor layer 203 may represent a silicon layer, whose crystallographic orientation differs from that of the layer 206. Moreover, a thickness of the layer 203 may be selected to be appropriate for the formation of field effect transistor elements in accordance with device requirements. For instance, for highly sophisticated CMOS devices, the thickness of the layer 203 may be selected to enable the formation of partially depleted or fully depleted advanced transistor devices, requiring a thickness of the respective channel regions of approximately 100 nm and less. Regarding a thickness of the layer 206, when it is provided as a separate layer above the base substrate 201, no particular constraints have to be met except for sufficient process margins for an anisotropic etch process to be performed later to expose a portion of the layer 206 for an epitaxial growth process, in which the exposed portion acts as a crystal template.

The substrate 200 as shown in FIG. 2a may be manufactured by the following processes. The base substrate 201 comprising the layer 206 may be bonded to a substrate (not shown) bearing the semiconductor layer 203, wherein the insulating layer 204 may be formed on the layer 206 of the base substrate 201, on the layer 203 or on both of these layers prior to bonding the base substrate 201 and the additional substrate bearing the layer 203. For example, the layer 203 and/or the layer 206 may be oxidized prior to the bonding process to form, after bonding, commonly the insulation layer 204. In other embodiments, an appropriate insulating layer may be formed on one or both of the layers 203, 206 by any deposition techniques, such as plasma enhanced chemical vapor deposition (PECVD). Thereafter, the base substrate 201 and the additional substrate may be attached to each other while providing pressure and heat according to well-established bond techniques. Thereafter, a portion of the additional substrate may be removed to leave behind the layer 203 firmly attached to the base substrate 201. The removal of excess material of the additional substrate may be accomplished by any grinding and/or etching techniques or may be achieved by forming a cleavage area by implanting hydrogen or helium as is well known in smart cut technologies for forming SOI substrates by wafer bonding and wafer cleaving.

FIG. 2b schematically shows the substrate 200 in a further advanced manufacturing stage. Here, a stack of layers is formed above the layer 203, which may be used for forming an opening in the layer 203. In the embodiment shown, a thin silicon dioxide layer 207 having a thickness of several nm, for instance approximately 5 nm, is formed on the layer 203 followed by a silicon nitride layer 208 having a thickness in the range of approximately 20-40 nm. Finally, a silicon dioxide layer 209 is formed on the nitride layer 208 with a thickness that is appropriate for acting as an etch mask during a subsequent anisotropic etch process. For example, the layer 209 may have a thickness in the range of approximately 100-200 nm. Moreover, a resist mask 210 is formed above the layer 209 with an opening 210a having a size and shape which substantially correspond to the size and shape of an opening to be formed in the layers 209, 208, 207 and the semiconductor layer 203 and the insulation layer 204.

The substrate 200 as shown in FIG. 2b may be formed by well-established process techniques involving the deposition or oxidation of the layer 207 followed by the deposition of the layers 208, 209 by, for instance, PECVD. Next, the resist mask 210 is formed by well-established lithography techniques. Thereafter, the layer 209 may be patterned by means of a selective anisotropic etch process, using the resist mask 210 as an etch mask. After opening the layer 209, the resist mask 210 may be removed. Subsequently, a further etch process of highly anisotropic nature may be performed for opening the layer 208 and 207 and etching through the semiconductor layer 203 and the insulation layer 204, wherein during the etching a single etch chemistry or different etch chemistries in accordance with well-established recipes may be used. During this etch process, the patterned layer 209 is used as an etch mask.

FIG. 2c schematically shows the substrate 200 after the above-described etch process with an opening 211 formed in the layers 209, 208, 207, 203 and 204, wherein the opening 211 extends down to the semiconductor layer 206. Moreover, sidewall spacers 212 are formed on sidewalls of the opening 211 to at least cover the semiconductor layer 203. The sidewall spacers 212 may be formed by well-established spacer techniques, that is, by depositing an appropriate spacer material such as silicon nitride by a substantially conformal deposition technique and by subsequently anisotropically etching the spacer layer. It should be noted that a thin oxide layer (not shown) may be formed prior to the deposition of the spacer layer to reliably stop the anisotropic etch process of the spacer layer without unduly damaging the exposed portion of the layer 206. By controlling an “over-etch time,” the height of the sidewall spacers 212 may be adjusted in accordance with process requirement as long as the layer 203 remains covered. Thereafter, a clean process may be performed to remove contaminants from the exposed portion of the semiconductor layer 206, such as the residues of an oxide liner, and the like, wherein simultaneously the layer 209 and possibly an upper portion of the sidewall spacers 212 may be removed unless the upper portion has not been removed during the preceding etch process due to a respective over-etch time.

Thereafter, the substrate 200 is exposed to a deposition atmosphere designed to deposit a semiconductor material on the exposed portion of the layer 206, wherein the epitaxially grown semiconductor material takes on the same or substantially the same crystalline structure as the underlying exposed portion of the semiconductor layer 206. In a particular embodiment, the exposed portion of the layer 206 may represent a silicon layer of specified crystallographic orientation, which is also translated into the epitaxially grown material within the opening 211. After the epitaxial growth process, any crystalline excess material deposited by the epitaxial growth process over the opening 211 and over portions covered by the layer 208 may be removed by chemical mechanical polishing (CMP), thereby also planarizing the resulting surface. During the CMP process, the layer 208 may also be reduced in thickness.

FIG. 2d schematically shows the substrate 200 after the above-described epitaxy and CMP process, thereby producing the layer 208 having a reduced thickness, now indicated as 208a, and a crystalline semiconductor material 217. Moreover, a mask layer 213 is formed above the layer 208a and the crystalline semiconductor material 217 grown within the opening 211. The mask layer 213 may be comprised of any appropriate material, such as silicon dioxide, with a thickness that is appropriate to substantially block a specified ion species that may locally be introduced in a subsequent SIMOX procedure. For instance, a thickness of the mask layer 213 may be in the range of approximately 200-300 nm. Thereafter, the mask layer 213 is patterned by photolithography to expose the semiconductor material 217 epitaxially grown in the opening 211.

FIG. 2e schematically shows the substrate 200 after the patterning of the layer 213 to form an opening 213A therein, thereby exposing the semiconductor material 217 grown in the opening 211 to an ion implantation process 215. The ion implantation 215 is performed with a high dose, such as approximately 10¹⁷-10¹⁸ ions/cm², with an implantation energy designed to deposit the essential amount of ion species within a region 216 at a desired depth. In one particular embodiment, the implantation energy is selected to position the implant region 216 substantially at the same approximate depth as the insulation layer 204. As is well known, the average penetration depth of implanted ions depends on the implantation energy, the ion species to be introduced and the type of material in which the ion species is to be implanted. Hence, appropriate implant parameters may be determined on the basis of simulations and/or test runs to obtain the desired depth and size of the implantation region 216. As previously mentioned, the implantation 215 is designed in accordance with established SIMOX techniques, that is, the temperature of the substrate 200 is preferably maintained at an elevated level, such as 400-600° C., to simultaneously heal, at least to a certain degree, implantation-induced lattice damage as the implantation continues. Consequently, significant crystal damage is avoided and a sufficient amount of “information” of the crystalline lattice is preserved in the material 217 so that in a subsequent anneal cycle the crystalline structure of the material 217 in the opening 211 may substantially be restored, while the implantation region 216 is transformed into a buried insulation layer, such as a buried oxide layer, when the ion species comprises oxygen and/or molecular oxygen. In other embodiments, other ion species may be introduced by the process 215, such as nitrogen, to form silicon nitride in the implant region 216.

Consequently, after the anneal process, the crystalline material 217 is positioned above a buried insulation layer 216a, wherein at least the crystallographic orientation of the material 217 is substantially identical to that of the semiconductor layer 206. In one particular embodiment, the semiconductor layer 206 is comprised of silicon of a specified crystallographic orientation and the semiconductor material 217 also comprises silicon having the same crystallographic orientation as the layer 206. In other embodiments, the material 217 may be selected to create a certain intrinsic strain after the epitaxial growth, for instance by depositing a mixture of silicon and germanium or silicon and carbon, when the underlying semiconductor layer 206 is comprised of silicon. In this case, the semiconductor material 217 may be strained due to a slight and adjustable mismatch between the lattice constant of silicon/germanium and silicon/carbon on the one side, and the underlying silicon of the layer 206 on the other side.

FIG. 2f schematically shows the substrate 200 with the layers 213, 208a and 207 removed and with trench isolation structures 202 formed on the locations of the sidewall spacers 212 (FIG. 2e). Consequently, the substrate 200 comprises a first region 205a having formed therein the semiconductor material 217 with a buried insulation layer 216A formed from the implant region 216 (FIG. 2e), thereby providing the potential for forming circuit elements in and on the region 205a on the basis of SOI architectures. Laterally separated by the trench isolations 202 are formed regions 205b having the same basic configuration with respect to the isolation to the base substrate 201, i.e., providing the potential for forming circuit elements in conformity with the SOI architecture, as the region 205a, wherein the semiconductor layer 203 provides for different characteristics compared to the material 217. In particular embodiments, the layer 203 and the material 217 may be comprised of silicon of different crystallographic orientations such as a (110) and a (100) orientation. For instance, the material 217 may have a (110) orientation and the layer 203 may have a (100) orientation, whereas, in other embodiments, the material 217 may have the (100) orientation and the layer 203 may exhibit the (110) orientation.

The substrate 200 as shown in FIG. 2f may be formed by well-approved wet chemical etch processes to remove the mask layer 213, the layer 208a and the layer 207, followed by well-established trench isolation techniques, involving advanced photolithography, anisotropic etch techniques and deposition methods. The substrate 200 may then be used for the formation of circuit elements on the basis of a common SOI-like architecture.

FIG. 2g schematically shows a semiconductor device 250, which is formed by using the substrate 200 as shown in FIG. 2f. The device 250 comprises a first transistor 251a formed in and on the region 205a, while a second transistor element 251b is formed in and on the region 205b. The first transistor 251a may represent a transistor whose performance may be enhanced by taking advantage of the specific characteristics of the semiconductor material 217. For example, the transistor element 251a may represent a P-channel transistor when the semiconductor material 217 comprises a (110) silicon. Similarly, the transistor 251b may represent a transistor element that may gain an increase of performance by taking advantage of the characteristics of the semiconductor layer 203. For example, the transistor 251b may represent an N-channel transistor, if the semiconductor layer 203 comprises a (100) silicon. It should be appreciated, however, that any other configurations may be within the scope of the present invention. That is, in other embodiments, the regions 205a and 205b may differ, alternatively or additionally, in other characteristics, such as internal strain and/or type of material. For example, the layer 203 may have been formed as a strained layer, for instance as a strained (100) silicon/carbon or silicon/germanium layer. In other cases, the material 217 may be formed as a strained material as is previously described.

During the fabrication of the device 250, well-established process techniques may be used or required new process techniques may be developed without requiring a distinction between the region 205a and 205b regarding a difference of SOI-like devices and “bulk” devices compared to conventional hybrid orientation substrates due to the similar SOI-like configuration, that is, a crystalline semiconductor region formed above a buried insulation layer. Consequently, well-approved methodology techniques and process techniques as used in SOI circuit architectures may be used or may readily be adapted in the fabrication of the device 250, while nevertheless the advantages of a hybrid substrate are preserved.

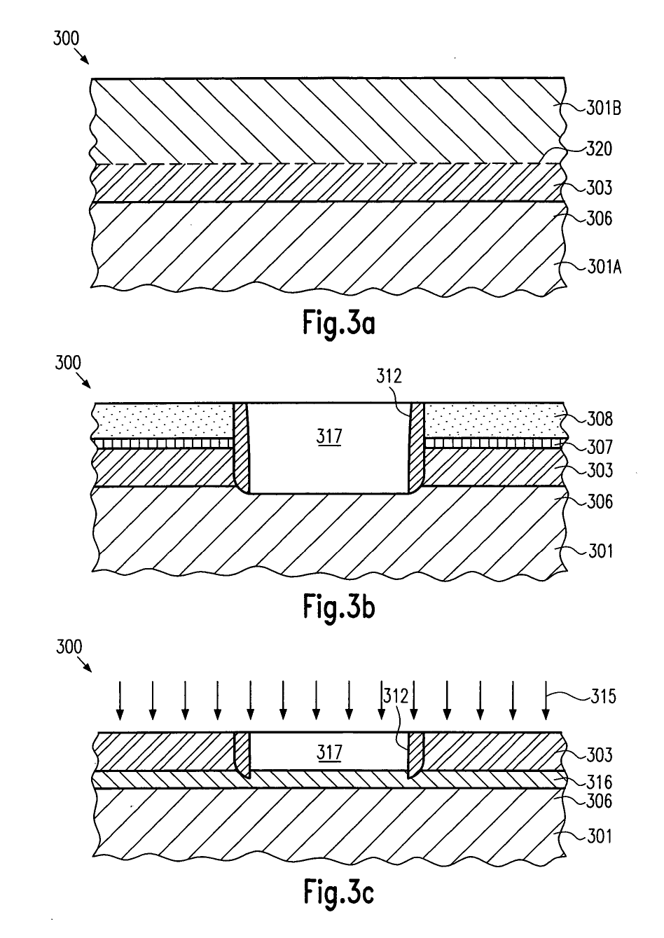

With reference to FIGS. 3a-3c, further illustrative embodiments of the present invention will now be described in more detail, wherein the formation of a buried insulation layer is performed entirely by means of a SIMOX technique to avoid any masking steps that may be required for the local formation of the buried insulation layer 216 (FIG. 2e).

In FIG. 3a, a substrate 300 comprises a base substrate 301a including a crystalline semiconductor layer 306 having a defined characteristic, such as a specific crystallographic orientation. A second substrate 301b having formed thereon a second crystalline semiconductor layer 303 having a specified characteristic differing from that of the layer 306 is attached to the base substrate 301a such that the layers 303 and 306 are in direct contact. Moreover, a cleavage region 320 may be provided in the substrate 301b to define, at least to a certain degree, a thickness of the crystalline semiconductor layer 303. The cleavage region 320 may be provided in the form of an implant region with a high amount of light atoms, such as hydrogen or helium.

As is also discussed with reference to the semiconductor layers 206, 203 in FIGS. 2a-2g, the layers 306, 303 may have corresponding characteristics wherein, in particular embodiments, the layers 303, 306 may represent silicon-based semiconductor layers having a different crystallographic orientation. Moreover, the substrates 301a, 301b may represent bulk semiconductor substrates formed of appropriate materials having the desired characteristics.

A typical process for forming the substrate 300 as shown in FIG. 3a may involve wafer bond techniques to adhere the substrate 301b to the substrate 301a by exerting pressure and heat, after the cleavage region 320 has been formed, for instance, by ion implantation of hydrogen or helium on the basis of well-established implantation parameters. After bonding the substrate 301b and 301a by directly contacting the semiconductor layers 303, 306, the substrate 301b may be cleaved, which may require an additional heating step to produce sufficient “bubbles” within the cleavage region 320 to enable the separation of the remaining portion of the substrate 301b from the layer 303. Thereafter, the resulting surface of the exposed layer 303 may be planarized by a CMP process. Thereafter, the fabrication process may be continued as is also described with reference to FIGS. 2b and 2c for forming a respective etch mask to etch through the layers 303, 306.

FIG. 3b schematically shows the substrate 300 after the completion of a corresponding fabrication sequence so that the substrate 300 now comprises an epitaxially grown semiconductor material 317 having substantially the same characteristics as the underlying semiconductor layer 306. The material 317 is formed within a stack of dielectric layers 308 and 307, for instance comprised of silicon nitride and silicon dioxide, and within the crystalline semiconductor layer 303. Moreover, sidewall spacers 312 are formed on sidewalls of an opening that has been formed prior to an epitaxial growth, during which the sidewall spacers 312 avoid growth of the crystalline material 317 having the characteristics of the layer 303. Regarding any details of the epitaxial growth, the formation of the sidewall spacer 312 and the like, it is referred to the corresponding components 212, 208, 207 described with reference to FIGS. 2b-2h. The substrate 300 may then be subjected to a CMP process thereby removing excess material of the epitaxially grown material 317 and also removing a certain amount of the layer 308. After completion of the CMP process, the residuals of the layer 308 and the layer 307 may be removed by well-established wet chemical etch processes to expose the material 317 and the layer 303.

FIG. 3c schematically shows the substrate 300 after completion of the above-described process sequence. Moreover, the substrate 300 is subjected to an ion implantation 315 in conformity with the SIMOX technique to form a buried insulation layer 316 in or below the layer 303 and the material 317, thereby providing an SOI-like configuration of different semiconductor regions formed above a buried insulation layer. With regard to the ion implantation 315 and the characteristics of the buried insulation layer 316, the same criteria apply as previously discussed with reference to the ion implantation 215 and the buried insulation layer 216. Thereafter, the further processing may be continued by the formation of isolation structures as is also described with reference to FIG. 2f.

It should be appreciated that the regions 205a, 205b, 305a and 305b, although shown to correspond to transistor active regions, may in other embodiments represent increased areas within a die region of the substrate 200 or 300, or may even represent an extended area of the substrate 200 or 300 including a plurality of die regions. In this way, device performance may be adapted in a more “global” fashion across the substrate 200 or 300 to impart specific “substrate characteristics” to desired substrate areas or die areas.

As a result, the present invention provides a new technique that enables the formation of a hybrid semiconductor substrate having formed thereon semiconductor regions of different characteristics, and in particular regions of different crystallographic orientation, wherein a buried insulation layer is formed below each of these different crystalline semiconductor regions. Hereby, well-established techniques of the SIMOX procedure may be used to partially or completely provide a buried insulation layer after the epitaxial growth step. Since circuit elements may now be formed in and on the differently designed crystalline regions on the basis of a common architecture, such as an SOI regime, well-established process and methodology techniques may be used, or corresponding techniques may be developed commonly for each of the different semiconductor regions, thereby significantly enhancing process efficiency and reducing production costs compared to the formation of integrated circuits on the basis of conventional hybrid orientation substrates.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a hybrid semiconductor substrate by forming a first crystalline semiconductor layer having a first characteristic above a second crystalline semiconductor layer having a second characteristic differing from said first characteristic;
forming an opening in said first crystalline semiconductor layer to expose a portion of said second crystalline semiconductor layer;
forming a crystalline semiconductor material in said opening by selective epitaxial growth to form said crystalline semiconductor material having said second characteristic; and
forming a buried insulation layer in said hybrid substrate under said formed crystalline semiconductor material in said opening by ion implantation and annealing.

2. The method of claim 1, wherein forming said hybrid substrate comprises providing an insulation layer between said first and second crystalline semiconductor layers.

3. The method of claim 2, wherein said opening is formed through said first crystalline semiconductor layer and said insulation layer to expose said portion of said second crystalline semiconductor layer.

4. The method of claim 3, further comprising forming an implantation mask to cover an area outside said opening and to expose said semiconductor material selectively grown in said opening prior to said ion implantation.

5. The method of claim 4, wherein an implantation energy is selected to deposit a peak concentration of an implant species at a depth that substantially corresponds to a depth of said insulation layer.

6. The method of claim 1, wherein an ion species implanted during said ion implantation comprises at least one of oxygen and molecular oxygen.

7. The method of claim 1, wherein said first characteristic represents a first crystallographic orientation and said second characteristic represents a second crystallographic orientation.

8. The method of claim 1, wherein forming said opening comprises forming a hard mask on said first crystalline semiconductor layer with a size and shape corresponding to said opening and selectively etching said first crystalline semiconductor layer.

9. The method of claim 1, further comprising forming a trench isolation enclosing said semiconductor material selectively grown in said opening, said trench isolation extending at least to said buried insulation layer.

10. The method of claim 9, further comprising forming a first transistor in and on said first crystalline layer and forming a second transistor in and on said semiconductor material selectively grown in said opening.

11. The method of claim 10, wherein said first crystalline semiconductor layer represents a silicon layer having one of a (110) orientation and a (100) orientation and said second crystalline semiconductor layer represents the other one of said (110) and (100) orientations.

12. The method of claim 1, wherein said hybrid substrate is formed by bonding a first crystalline substrate having said first characteristic to a second crystalline substrate having said second characteristic and removing a portion of said first substrate.

13. The method of claim 12, wherein said ion implantation is performed with an implantation energy to deposit an ion species for said buried insulation layer at a depth that is within said first crystalline semiconductor layer.

14. A substrate for forming transistor elements, comprising:
a base substrate;
a buried insulation layer formed on said base substrate;
a first crystalline semiconductor region formed on said buried insulation layer and having a first characteristic representing at least one of a crystallographic orientation, a type of semiconductor material and an intrinsic strain;
a second crystalline semiconductor region formed on said buried insulation layer and having a second characteristic differing from said first characteristic and representing at least one of a crystallographic orientation, a type of semiconductor material and an intrinsic strain; and
an isolation structure laterally isolating said first and second semiconductor regions.

15. The substrate of claim 14, wherein said first and second characteristics represent first and second crystallographic orientations.

16. The substrate of claim 14, wherein said base substrate is comprised of semiconductor material being of the same type and having the same characteristic as one of said first and the second semiconductor regions.

17. The substrate of claim 15, wherein said first and second semiconductor regions are comprised of silicon having a (110) and a (100) orientation, respectively.

18. The substrate of claim 17, wherein a thickness of said first and second crystalline semiconductor regions is approximately 100 nm or less.

19. A semiconductor device, comprising:
a base substrate;
a buried insulation layer formed on said base substrate;
a first crystalline semiconductor region formed on said buried insulation layer and having a first characteristic representing at least one of a crystallographic orientation, a type of semiconductor material and an intrinsic strain;
a second crystalline semiconductor region formed on said buried insulation layer and having a second characteristic differing from said first characteristic and representing at least one of a crystallographic orientation, a type of semiconductor material and an intrinsic strain;
an isolation structure laterally isolating said first and second semiconductor regions;
a first transistor element formed in and on said first crystalline semiconductor region; and
a second transistor element formed in and on said second crystalline semiconductor region.

20. The semiconductor device of claim 19, wherein said first and second characteristics represent first and second crystallographic orientations.

21. The semiconductor device of claim 19, wherein said base substrate is comprised of semiconductor material being of the same type and having the same characteristic as one of said first and the second semiconductor regions.

22. The semiconductor device of claim 20, wherein said first and second semiconductor regions are comprised of silicon having a (110) and a (100) orientation, respectively.

23. The semiconductor device of claim 22, wherein a thickness of said first and second crystalline semiconductor regions is approximately 100 nm or less.

24. The semiconductor device of claim 22, wherein said first transistor is a P-channel transistor and said second transistor is an N-channel transistor.
